(19) United States
(12) Patent Application Publication
(10) Pub. No.: US 2021/0040643 A1
(43) Pub. Date: Feb. 11, 2021

(54) SUSCEPTOR, METHOD FOR PRODUCING EPITAXIAL SUBSTRATE, AND EPITAXIAL SUBSTRATE

(71) Applicant: TOYO TANSO CO., LTD., Osaka (JP)

(72) Inventors: Takuya SAKAGUCHI, Kagawa (JP); Masato SHINOHARA, Kagawa (JP); Satoru NOGAMI, Kagawa (JP)

(73) Assignee: TOYO TANSO CO., LTD., Osaka (JP)

(21) Appl. No.: 16/611,903

(22) PCT Filed: May 11, 2018
(86) PCT No.: PCT/JP2018/018437

§ 371 Date: Oct. 9, 2020

(30) Foreign Application Priority Data
May 12, 2017 (JP) 2017-096003

(51) Int. Cl. C30B 25/12; C23C 16/458; C30B 23/06; C30B 25/20; C30B 29/36; C23C 16/32; H01L 21/02

(52) U.S. Cl. CPC C30B 25/12; C23C 16/458; C30B 23/063; C30B 25/20; H01L 21/02183; C23C 16/325; H01L 21/02293; H01L 21/02378; C30B 29/36

(57) ABSTRACT

A susceptor is a component for placing a SiC substrate in forming an epitaxial layer on a main surface of the SiC substrate. In this susceptor, a support surface and a recess are formed. The support surface is formed on lower position than an upper surface of the susceptor and supports an outer circumferential of the rear face of the SiC substrate. The recess is formed in the inside of the diametrical direction than the support surface, and at least the surface is made of a tantalum carbide, the depth of that is not in contact with the rear face of the Sic substrate in forming the epitaxial layer.

### TECHNICAL FIELD

The present invention relates mainly to a susceptor used in forming an epitaxial layer in a SiC substrate.

### BACKGROUND ART

Conventionally, it is known that an epitaxial layer is formed on a SiC substrate by chemical evaporation method, while supporting the SiC substrate on a susceptor. Therein, when the epitaxial layer is formed on the SiC substrate, owing to the difference in thermal expansion coefficient between the major surface and the rear face, it may warp to swell toward to the rear face side.

PTL 1 discloses a susceptor use for an epitaxially grown on a SiC substrate. This surface of the susceptor is coated with a TaC. In addition, in this susceptor, being formed a curved surface in accordance with the warpage of the SiC substrate in forming the epitaxial layer. In this configuration allows tensile stress applied to the TaC in forming the epitaxial layer can be reduced, thus allowing the TaC can be prevented from peeling off.

PTL 2 discloses a method of forming an epitaxial layer on a SiC substrate, using a susceptor with the TaC coated on the carbon. In the method of PTL 2, a SiC film formed on a surface of a susceptor is attached to the plate by high heating a susceptor loading on the plate. With this configuration, it is possible to prevent the SiC attached in a susceptor from becoming a particle source.

PTL 3 discloses a substrate holder used in forming a compound semiconductor film into a nitride semiconductor substrate. An anisotropic warpage may occur in one of the nitride semiconductor substrates. Therefore, in this substrate holder, an asymmetry recess being formed in accordance with the anisotropic warpage. In addition, the recess is configured not to contact with the nitride semiconductor substrate with a warpage has occurred. This configuration enables the in-plane temperature distribution of the nitride semiconductor substrate can be made uniform.

### CITATION LIST

PTL 1: Japanese Patent Application Laid-Open No. 2017/22320

PTL 2: Japanese Patent Application Laid-Open No. 2015/204434

PTL 3: Japanese Patent Application Laid-Open No. 2010/80614

### SUMMARY OF INVENTION

### Technical Problem

Here, in the process of forming the epitaxial layer on the SiC substrate needs to high heating, so that sublimation of the SiC occurs from the rear face of the SiC substrate, and the rear face of the SiC substrate may be rough. When the rear face of the SiC substrate is rough, in the device manufacturing later process to be performed, the rear face of the SiC substrate is difficult to adsorb. Therefore, a process (specular finishing and the like) for eliminating a roughness of the rear face of the SiC substrate is needed.

In PTL 1, the epitaxial layer is formed with the rear face of the SiC substrate having been contacted with a TaC film. Under these conditions, the rear face of the SiC substrate is rough because of the heat of the susceptor is directly transmitted. In PTL 2, in a state of mounting the SiC substrate on the susceptor, the rear face of the SiC substrate is floating. However, contact/non-contact when the nitride semiconductor substrate which a warpage has occurred are not described. PTL 3 is a technique applied to the nitride semiconductor substrate instead of a SiC substrate. Additionally, PTL 3 is intended to provide an in-plane temperature distribution of a nitride semiconductor substrate can be made uniform, however, a roughness of the rear face of the SiC substrate cannot be prevented by only making the in-plane temperature distribution uniform.

The present invention has been made in view of the circumstances described above, and a primary object of the present invention is to provide a susceptor used for an epitaxially grown on a SiC substrate with a rear face of the SiC substrate is less liable to roughness.

### Solution to Problem and Advantageous Effects

Problems to be solved by the present invention are as described above. Solutions to the problems and advantageous effects thereof will now be described.

A first aspect of the present invention provides a susceptor configuration as follows. The susceptor is a component for placing a SiC substrate in forming an epitaxial layer on the main surface of the SiC substrate. In this susceptor, a support surface and a recess are formed. The support surface is formed on the lower position than the upper surface of the susceptor and supports the outer circumferential of the rear face of the SiC substrate. The recess is formed in the inside of the diametrical direction than the support surface, and at least the surface is made of a tantalum carbide, the depth of that is not in contact with the rear face of the SiC substrate in forming the epitaxial layer.

These conditions, during formation processing an epitaxial layer, the rear face (in detail, part except the outer part) of the SiC substrate is not in contact with the susceptor, the heat of the susceptor is not directly transmitted. Moreover, for example, when the heat radiation rate of the tantalum carbide is lower temperature than that of graphite or the like, the rear face of the SiC substrate is less liable to high temperature. Therefore, by using the susceptor, a roughness on the rear face is not likely to appear in forming the epitaxial layer on the SiC substrate. Furthermore, for example, informing an epitaxial layer with large thickness, the roughness of the rear face of the SiC substrate will advance pronouncedly for the long processing time (the differences of the roughness of the rear face when compared with the graphite becomes more prominent). And then, the effect of the invention that the rear face of the SiC substrate is less liable to roughness can be used more effectively.

In the susceptor, it is preferable that the recess is the same depth as a whole.

In the above susceptor, it is preferable that the recess includes a side face of the recess which is a surface parallel to the substrate thickness direction and the bottom face of the recess which is a surface perpendicular to the substrate thickness direction.

Using such a shape, that can prevent contacting the SiC substrate with the susceptor in forming the epitaxial layer. Therefore, a suitable shaped susceptor can be realized according to the diameter, thickness and processing time of the SiC substrate and susceptor composition for example.

It is preferable that the susceptor includes the following configuration. That is, the susceptor being formed on the outer side in the diametrical direction of the support surface, and is having the regulation surface that regulates the movement of the SiC substrate in the diametrical direction. At least the surface of the support surface and the regulation surface are made of a tantalum carbide.

As a result, when the support surface and the regulation surface are the graphite for example, a SiC generated on the support surface and the regulation surface in forming the epitaxial layer may attach to the SiC substrate. However, using tantalum carbide can be prevent SiC from attaching. In addition, when the surface of recess is made of a SiC, the SiC sublimates in forming the epitaxial layer, then the lifespan of the susceptor may be shorten. However, the above configuration, in addition to the surface of recess, since the support surface and the regulation surface are the tantalum carbide, that could be prevented from sublimating in the whole portion where the SiC substrate is set. In this case, the lifespan of a susceptor can be improved.

It is preferable that the susceptor includes the following configuration. That is, the susceptor is configured by coating a layer having a different composition at least a part of the base material. The recess is provided by forming a tantalum carbide layer in the recess-shaped part of a base material.

This enables, while reducing the cost of the susceptor, a similar effect (to restrain the surface roughness of SiC substrate) is selectively obtained at a specific portion.

In the above susceptor, it is preferable that the base material is graphite, and is formed the SiC layer at least on the upper surface and the side face of the susceptor.

Because this enables, when the susceptor is covered with the tantalum carbide layer as a whole, SiC depositing on the tantalum carbide layer may be attached to the SiC substrate. As described above, by coating the susceptor upper surface and the susceptor side face with the SiC layer, can be prevented the SiC deposing on the tantalum carbide, resulting in advantages that include preventing contamination of the SiC substrate.

A second aspect of the present invention provides a method for producing an epitaxial substrate as described below. That is, this manufacturing method includes an epitaxial layer forming process of forming the epitaxial layer, by using the chemical vapor deposition whereby the SiC layer is placed on a susceptor. The susceptor used for the epitaxial layer forming process includes the support surface and the recess. The support surface is formed on the lower position than the upper surface of the susceptor and supports the outer circumferential of the rear face of the SiC substrate. The recess is formed in the inside of the diametrical direction than the support surface, and at least the surface is made of a tantalum carbide, the depth of that is not in contact with the SiC substrate in the epitaxial layer forming process.

A third aspect of the present invention provides an epitaxial substrate as structural described below. That is, this epitaxial substrate is that which an epitaxial layer is formed on the main surface of the SiC substrate. The surface roughness on the rear face of the epitaxial substrate is 1 μm or less, and the coefficient of variation of the carrier concentration in the epitaxial layer is 4 or less.

### BRIEF DESCRIPTION OF DRAWINGS

FIG. 1 A perspective view showing a configuration of a susceptor according to an embodiment of the present invention.

FIG. 2 A cross-sectional view of the side face of the substrate loading part of a susceptor.

FIG. 3 Cross-sectional views showing the state when loading a SiC substrate and forming an epitaxial layer.

FIG. 4 Figure views comparing the microscope picture of the rear face of the SiC substrate after the epitaxial layer formation with the case where the depth of a recess is 30 μm and 200 μm.

FIG. 5 Figure views comparing the variation coefficient of a carrier concentration distribution after the epitaxial layer formation with the case where the depth of a recess is 100 μm, 200 μm and 400 μm.

FIG. 6 Cross-sectional view of the side face of the substrate loading part of susceptor in Embodying Mode 1 of the present invention.

### DESCRIPTION OF EMBODIMENTS

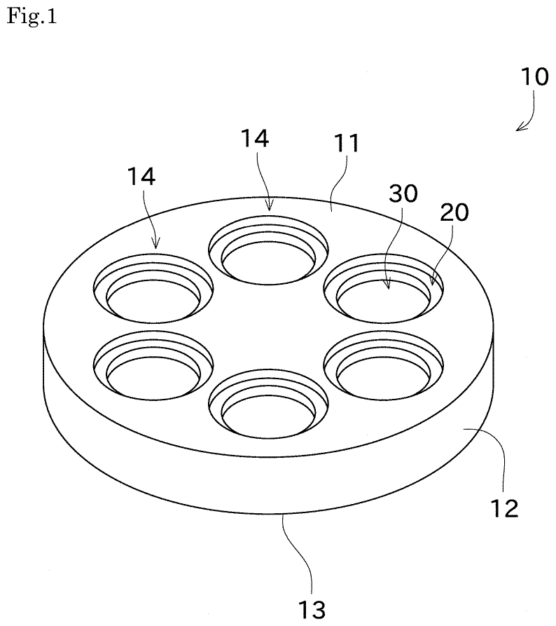

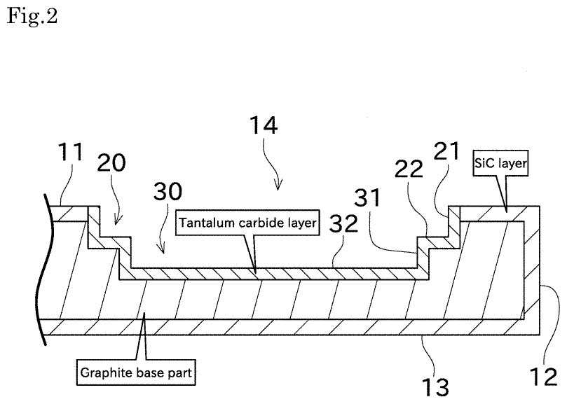

Next, an embodiment of the present invention will now be described with reference to the drawings. First, the configuration of a susceptor 10 is described with reference to FIGS. 1 and 2. FIG. 1 is a perspective view showing a configuration of the susceptor 10 according to an embodiment of the present invention. FIG. 2 is a cross-sectional view of the substrate loading part 14 of the susceptor 10.

The susceptor 10 is a component for loading a SiC substrate 50 in forming an epitaxial layer on the SiC substrate 50. In the process of forming the epitaxial layer, the SiC substrate 50 is loaded on the susceptor 10, the susceptor 10 is housed in a heating container, and a chemical vapor deposition method (CVD method) is performed. Then, the epitaxial layer is formed in the SiC substrate by introducing such as material gas in a high temperature environment. Herein, as the gas introduced into the heating container, for example, SiH₄ as a Si material, C₃H₈ and C₂H₂ as a C material, N₂ (n-type) and (CH₃)₃Al (p-type) for a dopant, HCl, SiH₂Cl₂, SiHCl₃, SiCl₄, and CH₃SiCl for the purpose of growth rate can be given. In addition, in the process of forming the epitaxial layer, the susceptor 10 may be rotated as a rotation axis of the central axis. As a result, the SiC substrate 50 on which the epitaxial layer is formed is referred to as an epitaxial substrate. In particular, in the specification, the substrate after the epitaxial layer is formed (immediately after) and before performing the subsequent process (the next process of mechanically or chemically processing the SiC substrate 50) is referred to the epitaxial substrate. And next process is, for example, a process of a thickness adjustment of the SiC substrate 50 and the processing of mirror finishing for the rear face of the SiC substrate 50. These processes may perform by machining of polishing or grinding and the like, or by a Si vapor pressure etching that etches the surface of the SiC substrate 50 by heating under the Si vapor pressure.

As shown in FIG. 1, the susceptor 10 has a disk shape (cylindrical shape), and one circular surface of the two is a susceptor upper surface 11 and the other is a susceptor bottom face 13. And, a curved surface (arc-shaped surface) connecting the susceptor upper surface 11 and the susceptor bottom face 13 is a susceptor side face 12. A plurality of the substrate loading part 14 are formed on the susceptor upper surface 11 of the susceptor 10.

Moreover, to explain the susceptor 10 from the perspective of the composition, As shown FIG. 2, it is a configuration that forms a TaC layer or a SiC layer on the base material made of graphite. The above-described susceptor upper surface 11, susceptor side face 12, and susceptor bottom face 13 consists of a SiC layer. Further, the surface (details given later) of the substrate loading part 14 consists of a TaC layer.

The substrate loading part 14 that is the part for loading the SiC substrate 50 and restricting its movements. As shown in FIG. 2, the substrate loading part 14 is the 2-step structure having an upper stage part 20 and a recess 30. In the upper stage part 20, a regulation surface 21 as a side face and a support surface 22 as a bottom surface are formed. In the recess 30, a side face of the recess 31 as a side surface and a bottom face of the recess 32 as a bottom face are formed.

The support surface 22 is a circular surface and supports the SiC substrate 50. This will be specifically described below. Here, the surface forming an epitaxial layer is referred to the main surface, among the surface of the SiC substrate 50. Consequently, in the present embodiment, the main surface of the SiC substrate 50 is a Si-surface or a C-surface and is circular surface. In addition, a surface on the reverse side from this main surface is referred to the rear face. Therefore, the inner diameter of the support surface 22 (the diameter of circle is composed of the outline in the inside of the diametrical direction of the support surface 22) is smaller than the diameter of the SiC substrate 50 applied (for instance, 2-inch, 3-inch, 4-inch and 6-inch). And also, the outer diameter of the support surface 22 (the diameter of circle is composed of the outline in the outside of the diametrical direction of the support surface 22) is larger than the diameter of the SiC substrate 50 applied. With this configuration, the support surface 22 supports the SiC substrate 50.

The regulation surface 21 is a circular arc surface which is formed so as to extend vertically upward from the ends of outside of a diametrical direction of the support surface 22. The regulation surface 21 restricts the movement of the SiC substrate 50 by contacting the SiC substrate 50 when the SiC substrate 50 loaded on the support surface 22 is moved in a diametrical direction (direction along the main surface or the rear face).

The side face of the recess 31 is a circular arc surface which is formed so as to extend vertically downward from the ends of inside of a diametrical direction of the support surface 22. Therefore, the position where the side face of the recess 31 is formed located on the inside of a diametral direction than the regulation surface 21. In addition, the height of the side face of the recess 31 (the length in the substrate thickness direction) may be lower, the same or higher than the height of the regulation surface 21.

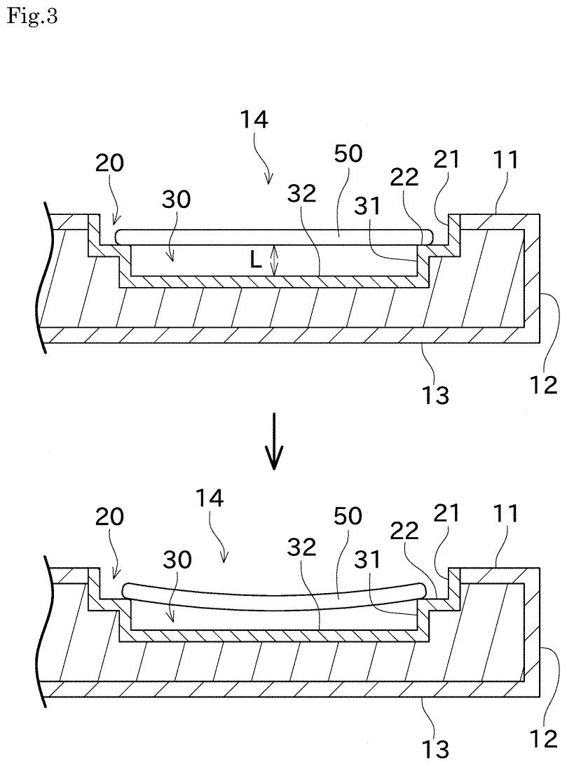

The bottom face of the recess 32 is a circular arc surface which is formed so as to extend horizontally from the ends of lower side of the side face of the recess 31. Therefore, the diameter of the bottom face of the recess 32 is the same as the inner diameter of the support surface 22. Specifically, at least either for the regulation surface 21 and the side face of the recess 31 may be inclined with respect to the substrate thickness direction. In this case, for example, the diameter of the bottom face of the recess 32 is smaller than the inner diameter of the support surface 22. Further, in this present embodiment, the length from the bottom face of the recess 32 to the support surface 22 (specifically, the length from the bottom face of the recess 32 to the virtual plane including the support surface 22) is referred to as the depth of the recess, and the depth of the recess at the center in the diametrical direction of the bottom face of the recess 32 (the length with “the symbol L” in FIG. 3) is referred to as the depth of the central recess. In addition, in this embodiment, although the depth of the recess is the same length over the recess 30, and may different according to its position.

As shown in FIG. 2, in this present embodiment, all of the surfaces such as the regulation surface 21, the support surface 22, the side face of the recess 31 and the bottom face of the recess 32 are composed of a tantalum carbide layer.

Next, using the susceptor 10 in the present embodying mode, the effect of forming an epitaxial layer will be described with reference to FIG. 3. to FIG. 5.

As described above, when the epitaxial layer is formed on the SiC substrate 50, owing to the difference in thermal expansion coefficient between the major surface and the rear face, it may warp to swell toward to the rear face side. The Figure below of the FIG. 3 shows the SiC substrate 50 is warped.

As shown in FIG. 3, the recess 30 in this present embodiment, the depth of that is not in contact with the back side of SiC substrate 50 and the bottom face of the recess 32 in forming the epitaxial layer (for example, 150° C. to 1700° C.)(that is, with SiC substrate 50 is warped). It is estimated that this depth will be changed according to the diameter of the SiC substrate 50.

Herein, it is considered that the roughness of the rear face of the SiC substrate is relate to the depth of a recess. For example, when the depth of the recess is shallow, the distance between the rear face of the SiC substrate and the bottom face of the recess will be reduced, thereby it is likely that the heat is transmitted and the rear face is to be rough.

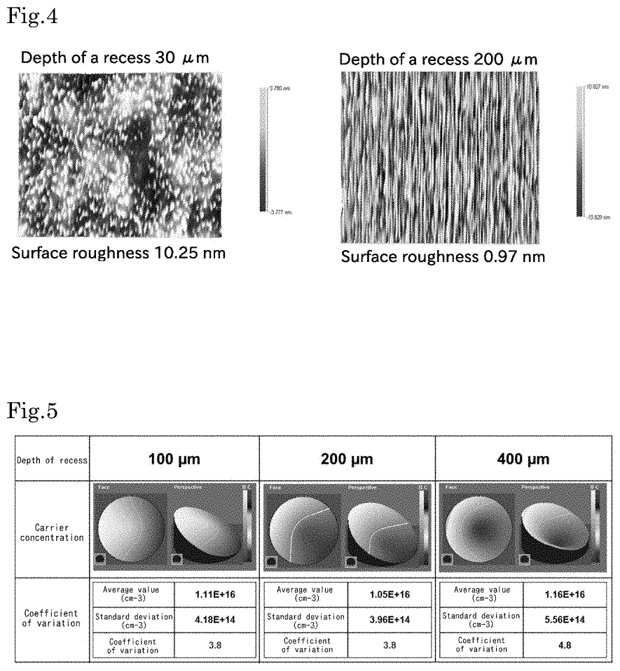

In order to verify this point, on a susceptor of which the recess had a depth of 30 μm and 200 μm, the experiment has been performed to measure the rear face after the formation of an epitaxial layer on the 2-inch SiC substrate using the white differential interference microscope (the surface of the recess is graphite). FIG. 4 is an arithmetic surface roughness Ra (surface roughness, hereinafter) that a photomicrograph and the rear face obtained in this experiment. As shown in FIG. 4, it was verified that the above considerations were correct, from the following it could be validated that, when a susceptor having a depth of recess 30 μm is used, the surface roughness to be 10.25 nm, when a susceptor having a depth of recess 200 μm is used, the surface roughness to be 0.97 nm, respectively.

FIG. 5 is a chart diagramming of the experimental results that verified the relationship between the depth of the recess of the susceptor whose surface of recess is made of a tantalum carbide, and the coefficient variation (value obtained by dividing the standard deviation by the average value) of the nitrogen-doping (carrier concentration) when using a 2-inch SiC substrate. As shown in FIG. 5, when the depth of the recess is 100 μm and 200 μm, the coefficient variation of the nitrogen-doping is the both depth are the same 3.8 (that is, less than 4), and when that depth is 400 μm, the coefficient variation of the nitrogen-doping will be increased (nitrogen-doping will be non-uniform). And thus, the depth of the recess of the susceptor is preferably 100 μm to 200 μm. It should be understood that when the depth of the recess is not uniform, the length of the central recess has a large impact on the rear face of the SiC substrate 50, In that case, the length of the recess preferably is between 100 μm to 200 μm.

In addition, the heat radiation rate of the tantalum carbide is lower than that of graphite. In this embodiment, because of the side face of the recess 31 and the bottom face of the recess 32 are made of tantalum carbide, the heat of the susceptor 10 is hardly transmitted to the rear face of the SiC substrate 50. Therefore, roughness of the rear face of the SiC substrate 50 with heating is less likely to be occur. In this result, in use of the susceptor 10 in this present embodiment, the rear face of the SiC substrate 50 on which the epitaxial layer is formed is less likely to be rough than when the surface of the recess having a susceptor made of graphite. Therefore, in this embodiment, it is assumed that the surface roughness of the rear face of the SiC substrate 50 is 1 nm (in detail, 0.97 nm) or less. And, the surface roughness of the rear face of the SiC substrate 50 is 0.4 nm or more. That surface roughness is the roughness of the rear face that when an epitaxial layer having a thickness of 10 μm is formed on the main surface by formation processing for 1 hour as an epitaxial layer formation rate of 10 μm/h. Furthermore, for example, when forming a large thickness epitaxial layer, the roughness of the rear face of the SiC substrate 50 will advance pronouncedly for the long processing time. And then, the effect that the rear face of the SiC substrate 50 is less liable to roughness can be used more effectively.

A variation of the embodiment described above will now be described. In the embodiment described above, the shape or component of the susceptor 10 (particularly, the shape of the recess 30), when the rear face of the Sic substrate 50 is not in contact with the bottom face of the recess 32 in forming the epitaxial layer, may have a shape differs from that of the above-described embodiments.

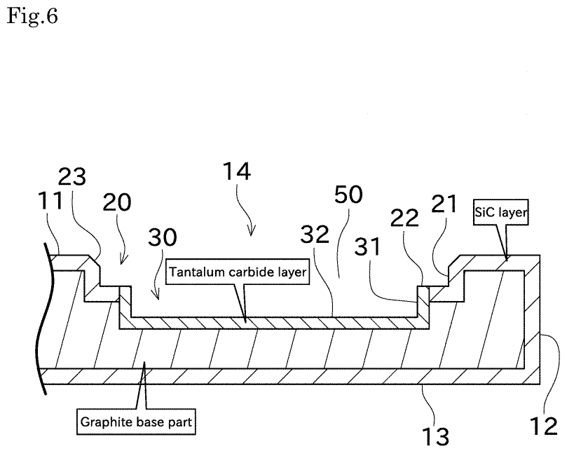

FIG. 6 is a cross-sectional view of the side face of the substrate loading part 14 of the susceptor 10 in Embodying Mode 1 of the present invention. The susceptor 10 in Embodying Mode 1 of the present invention that the chamfer 23 are formed all over the top of the upper stage part 20. Accordingly, when placing the SiC substrate 50, prevented from damage to the SiC substrate 50 caused by contact between the susceptor 10 and the SiC substrate 50, and is make it easy for loading.

In addition, the susceptor 10 in this present embodiment, which being formed on the outer side in the diametrical direction of the support surface 22, and is having the regulation surface 21 that regulates the movement of the SiC substrate 50 in the diametrical direction. At least the surface of the support surface 22 and the regulation surface 21 are made of a tantalum carbide.

Thus when the support surface 22 and the regulation surface 21 are the graphite for example, a SiC generated on the support 22 surface and the regulation surface 21 in forming the epitaxial layer may attach to the SiC substrate 50. However, using tantalum carbide can be prevent the SiC from attaching. In addition, when the surface of recess 30 is made of SiC, the SiC sublimates in forming the epitaxial layer, then the lifespan of the susceptor 10 may be shorten. On the other hand, the configuration in this present embodiment, in addition to the surface of recess 30, since the support surface 22 and the regulation surface 21 are the tantalum carbide, that could be prevented from sublimating in the whole substrate loading part 14 where the SiC substrate 50 is set. In this case, the lifespan of the susceptor 10 can be improved.

That is, the susceptor 10 in this present embodiment configured by coating a layer having a different composition (In this embodiment, SiC and tantalum carbide) at least a part of the base material (graphite base material). The recess 30 is configured by forming a tantalum carbide layer in the recess-shaped part of a base material.

This enables, while reducing the cost of the susceptor 10, a similar effect (to restrain the surface roughness of the SiC substrate 50) is selectively obtained at a specific portion.

In the susceptor 10 in this present embodiment, the base material is graphite, and is formed the SiC layer at least on the upper surface 11 and side face 10 of the susceptor.

Because this enables, when the susceptor 10 is covered with the tantalum carbide layer as a whole, SiC depositing on the tantalum carbide layer may be attached to the SiC substrate 50. As described above, by coating the susceptor upper surface 11 and the susceptor side face 12 with the SiC layer, can be prevented the SiC deposing on the tantalum carbide, resulting in advantages that include preventing contamination of the SiC substrate.

While a preferred embodiment and variations of the present invention have been described above, the configurations described above may be modified, for example, as follows.

In the embodiment described above, alternatively, to prepare another base material may be used instead of the base material made of graphite. In addition, the substrate may be coated with a layer having a different composition other than the SiC layer and the tantalum carbide layer. Also, the material may be omitted. And, when the surface of the recess 30 consists of the tantalum carbide, the other surface may be another material.

In the embodiment described above, the recess-shaped is an illustrative, and it may have a shape differs. In addition, in the embodiment described above, the support surface 22 is a circular surface and supports whole of the SiC substrate 50 (supporting over 360 degrees). Alternatively, it may be configured to support only the outer circumferential surface of the SiC substrate 50 (for example, configuration having the support surface 22 at every predetermined angle).

### REFERENCE SIGNS LIST

10 susceptor
14 substrate loading part
20 upper stage part
21 regulation surface
22 support surface
30 recess
31 side face of the recess
32 bottom face of the recess
50 SiC substrate

1. A susceptor on which a SiC substrate is placed in forming an epitaxial layer on a main surface of the SiC substrate comprising:
a support surface that is formed on a lower position than an upper surface of the susceptor, and on which an outer circumferential of a rear face of the SiC substrate is supported; and
a recess that is formed in an inside of a diametrical direction than the support surface, and at least the surface is made of a tantalum carbide, a depth of that is not in contact with the rear face of the SiC substrate in forming the epitaxial layer.

2. The susceptor according to claim 1, wherein
the recess is the same depth as a whole.

3. The susceptor according to claim 2, wherein
the recess includes a side face of the recess which is a surface parallel to the substrate thickness direction and a bottom face of the recess which is a surface perpendicular to the substrate thickness direction.

4. The susceptor according to claim 1, wherein
the susceptor being formed on the outer side in the diametrical direction of the support surface, and is having the regulation surface that regulates a movement of the SiC substrate in the diametrical direction; wherein
at least the surfaces of the support surface and the regulation surface are made of a tantalum carbide.

5. The susceptor according to claim 1, wherein
the susceptor is configured by coating a layer having a different composition at least a part of the base material,
the recess is provided by forming the tantalum carbide layer in the recess-shaped part of the base material.

6. The susceptor according to claim 5, wherein
the base material is graphite, and a SiC layer at least on the upper surface and the side face of the susceptor is formed.

7. A method of manufacturing an epitaxial substrate on which an epitaxial layer is formed on a main surface of a SiC substrate comprising:
an epitaxial layer forming process of forming the epitaxial layer, by using a chemical vapor deposition in such a manner that the SiC layer is placed on a susceptor,
wherein the susceptor used in the epitaxial layer forming process comprising:
a support surface that is formed on a lower position than an upper surface of the susceptor, and on which an outer circumferential of a rear face of the SiC substrate is supported; and
a recess that is formed in an inside of a diametrical direction than the support surface and at least the surface is made of a tantalum carbide, a depth of that is not in contact with the rear face of the SiC substrate in forming the epitaxial layer.

8. An epitaxial substrate on which an epitaxial layer is formed on a main surface of a SiC substrate wherein:
a surface roughness (Ra) on a rear face is 1 nm or less, and a coefficient of variation of a carrier concentration in the epitaxial layer is 4 or less.
